(19) United States
(12) Patent Application Publication
(10) Pub. No.: US 2025/0379546 A1
(43) Pub. Date: Dec. 11, 2025

(54) POWER AMPLIFYING CIRCUITRY UTILIZING HYBRID COUPLERS AND AN INDUCTIVE LOAD IN A DOHERTY ARCHITECTURE

(71) Applicants: STMicroelectronics International N.V., Geneva (CH); INSTITUT POLYTECHNIQUE DE BORDEAUX, TALENCE cedex (FR); UNIVERSITE DE BORDEAUX, Bordeaux (FR); CENTRE NATIONAL DE LA RECHERCHE SCIENTIFIQUE

(72) Inventors: Andreia CATHELIN, LAVAL-en-Belledonne (FR); Eric KERHERVE, Pessac (FR); Gwennael DIVERREZ, Issou (FR)

(21) Appl. No.: 18/737,101

(22) Filed: Jun. 7, 2024

(51) Int. Cl. H03F 1/02; H03F 3/24; H04B 1/04

(52) U.S. Cl. CPC H03F 1/0288; H03F 3/245; H03F 2200/451; H04B 1/04

(57) ABSTRACT

A power amplifying circuit and an RF transmission system configured to generate and transmit RF signals encoding various data are provided. An example power amplifying circuit, includes a first hybrid coupler, an auxiliary amplifier, a main amplifier, and a second hybrid coupler. The first hybrid coupler is configured to receive an input radio frequency (RF) signal and generate a first coupler first output signal and a first coupler second output signal offset by a phase offset. The second hybrid coupler is configured to combine the auxiliary amplifier output and the main amplifier output in synchronization to generate an RF output signal at a second coupler second output. The second coupler first output is electrically connected to an inductive load.

### TECHNOLOGICAL FIELD

Embodiments of the present disclosure relate generally to power amplifying circuitry, and more specifically to power amplifying circuitry utilizing a Doherty architecture.

### BACKGROUND

The increasing demand for multi-gigabit data rates has led to the development of radio frequency (RF) protocols in millimeter wave bands. Some of these RF protocols, including 5G, rely on beamforming antenna arrays that require wideband transmitters with high efficiency to generate complex signals with moderate output power. Specifically, spectrally efficient modulation schemes, for example, high-order quadrature amplitude modulation (QAM), may require a high peak-to-average power ratio (PAPR). In addition, the use of antenna arrays to perform beamforming may induce impedance variations at the output of an RF transmission system. Such requirements have led to a continued need to innovate power amplifying circuitry in a RF transmission system.

Applicant has identified many technical challenges and difficulties associated with power amplifying circuitry in RF transmission systems. Through applied effort, ingenuity, and innovation, Applicant has solved problems related to the generation of RF output signals using power amplifying circuitry by developing solutions embodied in the present disclosure, which are described in detail below.

### BRIEF SUMMARY

Various embodiments are directed to an example power amplifying circuit and an RF transmission system configured to generate and transmit RF signals encoding various data. An example power amplifying circuit, may comprise a first hybrid coupler, an auxiliary amplifier, a main amplifier, and a second hybrid coupler. The first hybrid coupler configured to receive an input radio frequency (RF) signal and generate a first coupler first output signal and a first coupler second output signal, wherein the first coupler first output signal and the first coupler second output signal are offset by a phase offset. The auxiliary amplifier configured to receive the first coupler first output signal, and generate an auxiliary amplifier output. The main amplifier configured to receive the first coupler second output signal, and generate a main amplifier output. The second hybrid coupler comprising a second coupler first output, and a second coupler second output, the second hybrid coupler configured to receive the auxiliary amplifier output and to receive the main amplifier output. The second coupler first output is electrically connected to an inductive load, and the auxiliary amplifier output and the main amplifier output are adapted to be combined in synchronization to generate an RF output signal at the second coupler second output.

In some embodiments, the first hybrid coupler and the second hybrid coupler are ninety-degree hybrid couplers, such that the phase offset of the first coupler first output signal and the first coupler second output signal is ninety degrees.

In some embodiments, the first hybrid coupler and the second hybrid coupler are twisted hybrid couplers.

In some embodiments, the main amplifier is biased to amplify the first coupler second output signal in an extended power operation class.

In some embodiments, the main amplifier is configured for Class AB operation.

In some embodiments, the auxiliary amplifier is configured for Class C operation.

In some embodiments, the power amplifying circuit further comprises a first adaptive biasing circuitry configured to generate a first adaptive biasing signal based on the input RF signal, wherein the first adaptive biasing signal defines an auxiliary power operation class of the auxiliary amplifier based on an amplitude of the input RF signal.

In some embodiments, the power amplifying circuit further comprises a second adaptive biasing circuitry configured to generate a second adaptive biasing signal based on the input RF signal, wherein the second adaptive biasing signal defines a main power operation class of the main amplifier based on the amplitude of the input RF signal.

In some embodiments, the auxiliary power operation class and the main power operation class are the same class.

In some embodiments, the main amplifier saturates at a power backoff level lower than a maximum RF power of the main amplifier.

In some embodiments, the inductive load is a passive electrical component.

In some embodiments, the inductive load has a reflection coefficient at or above 0.7.

In some embodiments, an imaginary impedance part of the inductive load is at least a factor of 15 greater than a real impedance part of the inductive load.

In some embodiments, an impedance of the inductive load is between 100 picohenries and 400 picohenries.

In some embodiments, the second hybrid coupler is associated with a reference impedance, wherein an impedance of the inductive load is determined based on the reference impedance.

In some embodiments, an observed impedance at an output of the main amplifier is two times the reference impedance in an instance in which a power level of the input RF signal is at or below the power backoff level.

In some embodiments, in an instance in which the input RF signal is above the power backoff level, the observed impedance at the output of the main amplifier is between two times the reference impedance and the reference impedance.

In some embodiments, in an instance in which the input RF signal is at the maximum RF power, the observed impedance at the output of the main amplifier is the reference impedance.

In some embodiments, the power backoff level is between three decibels and six decibels below the maximum RF power.

An example radio frequency (RF) transmission system is further provided. In some embodiments, the example RF transmission system comprises a signal generator, a power amplifying circuit, and an RF antenna. The signal generator configured to generate an input RF signal. The power amplifying circuit electrically connected to the signal generator, the power amplifying circuit comprising a first hybrid coupler, an auxiliary amplifier, a main amplifier, and a second hybrid coupler. The first hybrid coupler configured to receive an input RF signal and generate a first coupler first output signal and a first coupler second output signal, wherein the first coupler first output signal and the first coupler second output signal are offset by a phase offset. The auxiliary amplifier configured to receive the first coupler first output signal, and generate an auxiliary amplifier output. The main amplifier configured to receive the first coupler second output signal, and generate a main amplifier output. The second hybrid coupler, comprising a second coupler first output, and a second coupler second output and configured to receive the auxiliary amplifier output and the main amplifier output. Wherein the second coupler first output is electrically connected to an inductive load, and wherein the auxiliary amplifier output and the main amplifier output are combined in synchronization to generate an RF output signal at the second coupler second output. The RF antenna, configured to transmit the RF output signal across a transmission medium.

### BRIEF DESCRIPTION OF THE DRAWINGS

Reference will now be made to the accompanying drawings. The components illustrated in the figures may or may not be present in certain embodiments described herein. Some embodiments may include fewer (or more) components than those shown in the figures in accordance with an example embodiment of the present disclosure.

FIG. 1 illustrates a schematic of an example power amplifying circuit with an inductive load in accordance with an example embodiment of the present disclosure.

FIG. 2 illustrates a schematic of an example auxiliary amplifier in accordance with an example embodiment of the present disclosure.

FIG. 3 illustrates a schematic of an example main amplifier in accordance with an example embodiment of the present disclosure.

FIG. 4A-FIG. 4B illustrate operation of an example power amplifying circuit and an associated graph depicting power added efficiency of the power amplifying circuit in an instance in which the power level of the input RF signal is below a power backoff level in accordance with an example embodiment of the present disclosure.

FIG. 5A-FIG. 5B illustrate operation of an example power amplifying circuit and an associated graph depicting power added efficiency of the power amplifying circuit in an instance in which the power level of the input RF signal is above a power backoff level in accordance with an example embodiment of the present disclosure.

FIG. 6 depicts an example impedance observed at the main amplifier in accordance with an example embodiment of the present disclosure.

FIG. 7A-FIG. 7B depict a relative bandwidth of a power amplifying circuit in accordance with an example embodiment of the present disclosure.

FIG. 8 depicts an example power amplifying circuit comprising adaptive biasing circuitry in accordance with an example embodiment of the present disclosure.

FIG. 9 depicts a schematic diagram of example adaptive biasing circuitry in accordance with an example embodiment of the present disclosure.

FIG. 10 depicts an example power amplifying circuit comprising adaptive biasing circuitry providing separate adaptive biasing signals to the auxiliary amplifier and the main amplifier in accordance with an example embodiment of the present disclosure.

FIG. 11 depicts an example RF transmission system comprising a power amplifying circuit in accordance with an example embodiment of the present disclosure.

### DETAILED DESCRIPTION

Example embodiments will be described more fully hereinafter with reference to the accompanying drawings, in which some, but not all embodiments of the inventions of the disclosure are shown. Indeed, embodiments of the disclosure may be embodied in many different forms and should not be construed as limited to the embodiments set forth herein; rather, these embodiments are provided so that this disclosure will satisfy applicable legal requirements. Like numbers refer to like elements throughout.

Various example embodiments address technical problems associated with amplifying an RF signal that is efficient up to deep power backoff, operable over a wide bandwidth, and resilient to changing voltage standing wave ratio (VSWR). As understood by those of skill in the field to which the present disclosure pertains, there are numerous example scenarios in which a power amplifying circuit may be utilized to efficiently generate an RF output signal up to deep power backoff, operable over a wide bandwidth, and resilient to changing VSWR.

For example, the constant demand to support multi-gigabit data rates has led to the development of radio frequency (RF) protocols in millimeter wave bands. Some of these RF protocols, including 5G, rely on beamforming antenna arrays to transmit RF output signals. Beamforming antenna arrays induce VSWR variations and consequently impedance variations at the output of the power amplifying circuit that may strongly degrade the performance of the power amplifying circuit.

In addition, spectrally efficient modulation schemes, for example, high-order quadrature amplitude modulation (QAM), are utilized to maximize data transmission. Spectrally efficient modulation schemes may require signals to be generated with a high peak-to-average power ratio (e.g., 9.6 dB). Thus, spectrally efficient modulation schemes require a power amplifying circuit to regularly operate at a deep power back off with a high power added efficiency (PAE).

Further, such protocols require operation over a wide frequency bandwidth. A frequency bandwidth is defined herein as wide in an instance in which the relative bandwidth is greater than 20%. Alternatively, a frequency bandwidth is defined herein as narrow in an instance in which the relative bandwidth is less than 10%. As a consequence, a power amplifying circuit supporting such RF protocols may need to operate over a wide bandwidth.

Some previously developed examples of power amplifier circuitry include Doherty power amplifiers and balanced power amplifiers. Doherty power amplifiers include a power splitter to separate the input RF signal on two paths, a primary power amplifier path comprising a main power amplifier polarized for example in class AB, and a peaking/auxiliary amplifier path comprising an amplifier polarized for example in class C. The peaking amplifier serves as an active load for the main amplifier.

In a Doherty power amplifier, at a low power level the peaking amplifier is switched off. As a result, the peaking amplifier has an infinite impedance at its output. A quarter wave impedance inverter transforms the equivalent impedance (defined as the output impedance of the peaking amplifier in parallel with the load impedance of the overall Doherty amplifier) into two times the optimal impedance at the output of the main amplifier. Thus, the main amplifier saturates 3 dB (half power) before its maximum power saturation.

At a medium power level, the peaking amplifier turns on gradually. The output impedance of the peaking amplifier progressively changes from an infinite impedance to the optimal impedance, and so does the equivalent impedance seen, after quarter wave transformation, by the main amplifier. As the peaking amplifier tends to turn on, the impedance at the output of the main amplifier gradually tends from two times the optimal impedance to the optimal impedance. The main amplifier thus gradually saturates towards its real saturation power.

At a high power level, the peaking amplifier of the Doherty power amplifier is fully on and has an output impedance equal to the optimal impedance. The main amplifier saturates at its maximum saturation power. The power recombination of the two amplifiers provides a 3 dB increase of the saturated output power to achieve 6 dB power back off. However, the Doherty power amplifier only operates in a narrow frequency bandwidth, due to the intrinsic limited frequency bandwidth of the quarter wave impedance transformer line (tuned inherently only to a narrow frequency band given by its physical parameters).

A balanced power amplifier consists of two amplifiers connected in parallel and configured to receive an input RF signal phase-shifted by 90° using quadrature hybrid couplers at the input and output of the balanced structure. The first hybrid coupler divides the input signal into two equal parts phase-shifted by 90°. The two quadrature signals are then amplified by two amplifiers in parallel. At the output, a second hybrid coupler recombines the two amplified signals towards the antenna. When the current of one amplifier increases due to a change in load impedance toward low impedances, the current of the other amplifier decreases, as its load impedance, conversely, moves toward high impedances, and vice versa. The load variations on the two amplifiers compensate each other. Contrary to the Doherty power amplifier, the balanced power amplifier may operate in a wide frequency bandwidth enabled if the couplers have such a wideband operation. Nevertheless, the balanced power amplifiers have intrinsic limited power backoff PAE behavior.

Other examples suffer from poor resilience to changes in VSWR, additional operational complexity, and/or mechanisms that consume additional power from the input RF signal.

The various example embodiments described herein utilize various techniques to generate an amplified RF output signal that is resilient to variations in VSWR, efficient up to deep power backoff, and supports a wide bandwidth (e.g., a relative bandwidth greater than 20%).

For example, in some embodiments, a power amplifying circuit in accordance with the present disclosure includes an input hybrid coupler and an output hybrid coupler. The input hybrid coupler is configured to split an input RF signal equally between two output ports resulting in a phase offset between the first output signal from the input hybrid coupler and the second output signal from the input hybrid coupler. The power amplifying circuit of the present disclosure further includes two amplifier devices, a main amplifier and an auxiliary amplifier.

The main amplifier is configured to receive the second output signal from the input hybrid coupler and amplify the second output signal within a first power operation class. For example, the main amplifier may be configured according to a class AB operation. The main amplifier is configured to amplify the second output signal for both low power input RF signals (e.g., below a power backoff level) and high power input RF signals (e.g., above the power backoff level).

The auxiliary amplifier is configured to receive the first output signal from the input hybrid coupler and amplify the first output signal within a second power operation class. For example, the auxiliary amplifier may be biased for class C operation. The auxiliary amplifier is configured to amplify the second output signal at medium and high power input RF signals (e.g., above the power backoff level).

The power amplifying circuit may further include an output hybrid coupler. The output hybrid coupler is configured to receive the amplified output from both the auxiliary amplifier and the main amplifier and combine the amplified outputs at the RF output signal. Combining the outputs from the auxiliary amplifier and the main amplifier enable the two amplifiers to compensate for each other at high power levels as the load impedance changes.

In addition, the output hybrid coupler includes an output isolation port. An inductive load is electrically connected to the output isolation port of the output hybrid coupler. The inductive load on the output isolation port reflects an inductance to the output of the main amplifier and the auxiliary amplifier. The signal reflected on the inductive load is dependent on the reflective coefficient of the inductive load, the phase shift introduced by the inductive load, and the operating power level of the auxiliary amplifier and the main amplifier.

During a low power mode (e.g., below the power backoff level), the auxiliary amplifier may be turned off. As a result, half of the signal sent by the main amplifier is transmitted to the inductive load. The inductive load may be configured such that during the low power mode of operation, the impedance seen at the output of the main amplifier is equivalent to two times the optimal impedance of the main amplifier. Such an impedance causes the main amplifier to saturate at a power backoff level (e.g., 3 dB before the maximum RF power of the main amplifier).

During a high power mode (e.g., above the power backoff level), both the main amplifier and the auxiliary amplifier are operating. Thus, the output signal from the main amplifier and the output signal from the auxiliary amplifier arrive at the inductive load in phase opposition and no signal is transmitted to the inductive load. As a result, the impedance observed at the output of the main amplifier is equal to the optimal impedance. Because the output impedance is equal to the optimal impedance during the high power mode, the main amplifier is allowed to again saturate at the maximum RF power.

As a result of the herein described example embodiments, the efficiency of a power amplifying circuit at a deep power backoff level may be greatly improved. In addition, the power amplifying circuit of the example embodiments supports a wide bandwidth and is resilient to variations in VSWR.

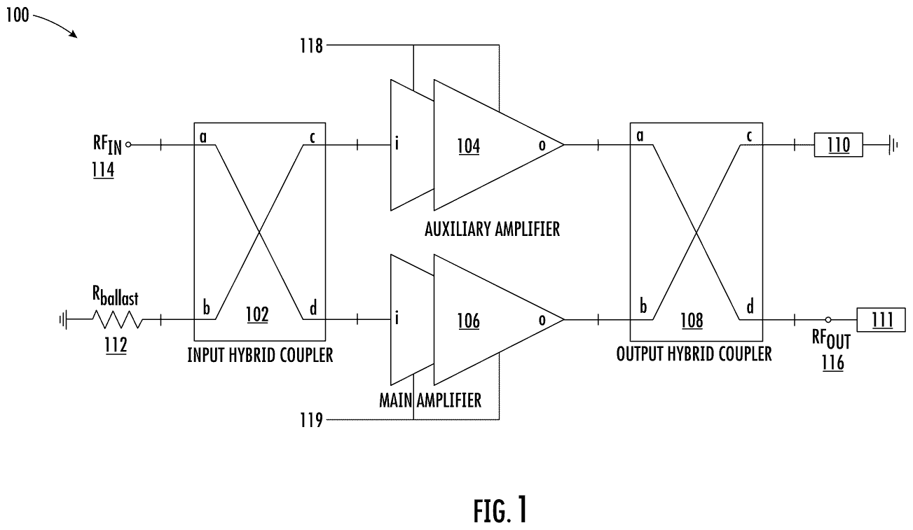

Referring now to FIG. 1, an example power amplifying circuit 100 is provided. As depicted in FIG. 1, the an example power amplifying circuit 100 includes an input hybrid coupler 102 (e.g., first hybrid coupler) with one input (102a), one isolation port (102b) and two outputs (102c, 102d). An input RF signal 114 is transmitted to the input hybrid coupler 102 on a first input 102a. The isolation port 102b of the hybrid coupler 102 is electrically connected to a ballast resistor 112. The ballast resistor 112 is selected to present the same impedance as the impedance seen at the input port 102a. As further depicted in FIG. 1, the first output 102c of the input hybrid coupler 102 is electrically connected to the input 104i of an auxiliary amplifier 104. Similarly, the second output 102d of the input hybrid coupler 102 is electrically connected to the input 106i of the main amplifier 106. As further depicted in FIG. 1, the an example power amplifying circuit 100 includes an output hybrid coupler 108 (e.g., second hybrid coupler) having two inputs (108a, 108b) and two outputs (108c, 108d). The first input 108a of the output hybrid coupler 108 is electrically connected to the output 104o of the auxiliary amplifier 104. Similarly, the second input 108b of the output hybrid coupler 108 is electrically connected to the output 106o of the main amplifier 106. The isolation output 108c is electrically connected to an inductive load 110. The second output 108d is configured to generate the RF output signal 116. As further depicted in FIG. 1, the auxiliary amplifier 104 may be configured to receive a bias signal 118 and the main amplifier 106 may be configured to receive a bias signal 119.

As depicted in FIG. 1, the power amplifying circuit 100 is configured to receive an input RF signal 114. An input RF signal 114 is any electromagnetic wave oscillating at a frequency within the RF, millimeter-wave and beyond spectrum and modulated to encode data. Modulation encoding techniques may include amplitude modulation (AM), frequency modulation (FM), phase shift keying (PSK), quadrature phase shift keying (QPSK), quadrature amplitude modulation (QAM), and so on. A transmitting device (not pictured) may be configured to generate the input RF signal 114 with encoded data to the power amplifying circuit 100.

As depicted in FIG. 1, the an example power amplifying circuit 100 includes an input hybrid coupler 102 and an output hybrid coupler 108. A hybrid coupler (e.g., input hybrid coupler 102, output hybrid coupler 108) is any electronic device including hardware and/or software devices configured to receive one or more RF signals and perform signal operations. For example, hybrid couplers may split and/or combine signals. Performing signal operations may introduce a phase offset, for example, the signal on the first output may have a phase offset with reference to the signal on the second output. In some embodiments, the phase offset may be 90 degrees.

In some embodiments, a hybrid coupler (e.g., input hybrid coupler 102, output hybrid coupler 108) may comprise a twisted hybrid coupler. A twisted hybrid coupler may utilize twisted conductive components within the hybrid coupler to change the electrical properties of the hybrid coupler. For example, twisted hybrid couplers may be utilized to support wideband behavior from the input RF signal 114. In addition, the twisted hybrid coupler may exhibit low insertion losses, avoiding PAE degradation across a wide frequency bandwidth. The twisted hybrid coupler may enable compact area integration with small XY form factor.

Utilization of hybrid couplers (e.g., input hybrid coupler 102 and output hybrid coupler 108) enable the power amplifying circuit 100 to be resilient to changes in VSWR. VSWR is a measure of how efficiently RF power is transmitted from a power amplifying circuit to an output antenna. The VSWR may change based on variations in impedance in the components of the power amplifying circuit 100, a transmission line, and the load at the antenna. Antennas utilized to perform beamforming operations may experience changes in load impedance and thus variation in VSWR. The output hybrid coupler 108 improves the standing wave behavior at the output. Indeed, any signal reflected by an antenna is reflected again by the two internal amplifiers towards the inductive load 110, where it is dissipated by the Joule effect. In addition, the hybrid coupler insertion losses (α) lower the VSWR seen at the internal amplifiers output. The equation connecting the reflection coefficients at the antenna (Γ_{ANT}) and internal amplifiers (Γ_{PA}) to α is: Γ_{PA}=α^{2▪}Γ_{ANT}. For example, a VSWR of 3:1 at the antenna will be seen as a VSWR of 2.4:1 at the amplifiers respective outputs for a hybrid coupler insertion loss of 0.6 dB.

The input hybrid coupler 102 is configured to receive the input RF signal 114 at the input 102a. As depicted in FIG. 1, the input RF signal 114 is split between the two outputs (102c, 102d). The first output signal of the input hybrid coupler 102 (e.g., first coupler first output signal) is transmitted to the input 104i of the auxiliary amplifier 104. The second output signal of the input hybrid coupler 102 (e.g., first coupler second output signal) is transmitted to the input 106i of the main amplifier 106. The output signals of the input hybrid coupler 102 are offset in phase by a phase offset. The hybrid coupler 102 may be configured to adjust the phase offset between the output signals. For example, in some embodiments, output signals of the input hybrid coupler (e.g., first coupler first output signal and first coupler second output signal) may be offset by ninety degrees. A hybrid coupler configured to offset the inputs by ninety-degrees may be referred to as a ninety-degree hybrid coupler.

As further depicted in FIG. 1, the power amplifying circuit 100 includes a ballast resistor 112 electrically connected to the input port 102b of the hybrid coupler 102. The ballast resistor 112 presents the same impedance to the input port 102b as the impedance present at the input port 102a. In some example embodiments, the input impedance of the ballast resistor 112 is 50 Ohms. The ballast resistor 112 ensures, inside the hybrid coupler 102 operation, that all the input power is equally spread over outputs 102c and 102d in the input hybrid coupler 102. The ballast resistor 112 is further configured to withstand strong power levels in the case of variations of VSWR.

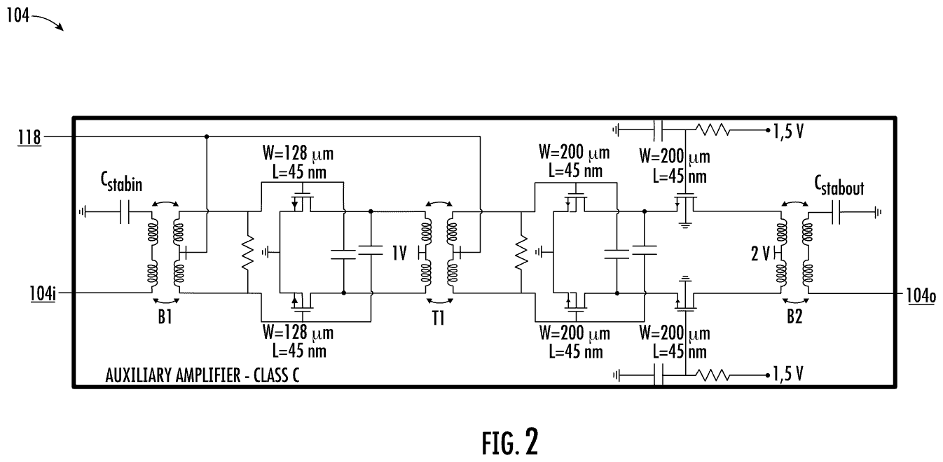

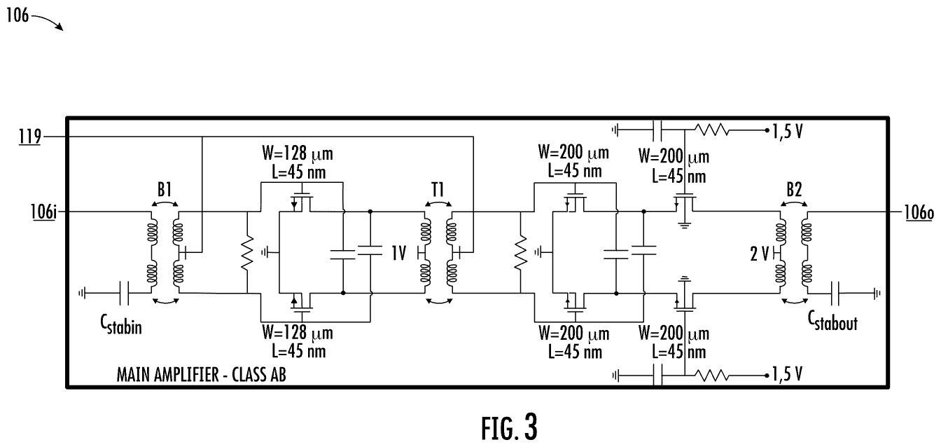

As further depicted in FIG. 1, the power amplifying circuit 100 includes a main amplifier 106 configured to receive an output of the input hybrid coupler 102 (e.g., first coupler second output signal) and an auxiliary amplifier 104 configured to receive an output of the input hybrid coupler 102 (e.g., first coupler first output signal). An amplifier is any electrical device configured to utilize a bias signal (e.g., bias signal 118, 119) to generate an output signal, such that the output signal is an increased version of the input signal. The output signal may include an increase in voltage, current, power, and/or another electrical characteristic of the input signal. A circuit schematic of a non-limiting example of an auxiliary amplifier is provided in FIG. 2. In addition, a circuit schematic of a non-limiting example of a main amplifier is provided in FIG. 3.

In some embodiments, the bias signal 118, 119 of an amplifier may be configured to define a power operation class (e.g., bias range) of the amplifier based on the electrical properties of the RF signal received at the input of the amplifier. For example, an amplifier may be configured to provide gain at any power level (e.g., extended power operation class). Similarly, an amplifier may be configured to provide gain only at high power levels (e.g., upper power operation class). High power levels, may be defined as power levels exceeding the power backoff level for the power amplifying circuit 100. An amplifier operating in the upper power operation class amplifies signals with a power level exceeding the power backoff level. In some examples, an amplifier may be configured to provide gain only at low power levels (e.g., lower power operation class). Low power levels may be defined as power levels at or below the power backoff level for the power amplifying circuit 100. An amplifier operating in the extended power operation class amplifies signals at any power level.

As shown in FIG. 1, the main amplifier 106 is configured to provide gain at any power level (e.g., an extended power operation class). In contrast, the auxiliary amplifier 104 is configured to provide gain at medium and high power levels (e.g., upper power operation class), for example, power levels exceeding the power backoff level for the power amplifying circuit 100.

In some embodiments, the power operation class of an amplifier may be configured by adjusting the bias signal 118, 119 according to a power operation class. For example, an amplifier may be configured for Class A operation, Class B operation, Class AB operation, Class C operation, and so on. Such classes define the conduction angle of the power amplifying transistor in an amplifier. The wider the conduction angle, the more the operation class is linear (for example Class A). On the other hand, an amplifier operates more efficiently with a smaller conduction angle, but the operation class is less linear (see for example Class C with a conduction angle less than 180 degrees). An amplifier configured for Class AB operation may seek to balance linear operation with efficient operation.

As described herein, in some embodiments, the main amplifier 106 is configured as class AB operating amplifier with a more linear operation. The auxiliary amplifier 104 is configured as a class C operating amplifier with more efficient operation but less linearity. The bias signals 118, 119 of the respective amplifiers may determine the power operation class of the amplifier. As depicted in FIG. 1, the auxiliary amplifier 104 may be configured for Class C operation by adjusting the bias signal 118. Thus, the auxiliary amplifier 104 is enabled in an instance in which the power level of the input RF signal 114 exceeds the power back-off level of the power amplifying circuit 100.

As further depicted in FIG. 1, the output hybrid coupler 108 is configured to receive the output signal (e.g., auxiliary amplifier output) from the auxiliary amplifier 104 (e.g., output 104o) at the first input 108a of the output hybrid coupler 108. In addition, the output hybrid coupler 108 is configured to receive the output signal (e.g., main amplifier output) from the main amplifier 106 (e.g., output 106o) at the second input 108b of the output hybrid coupler 108.

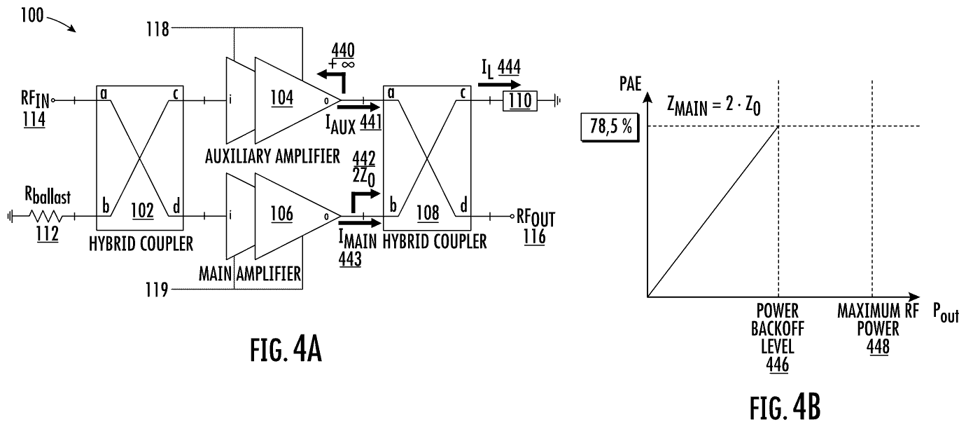

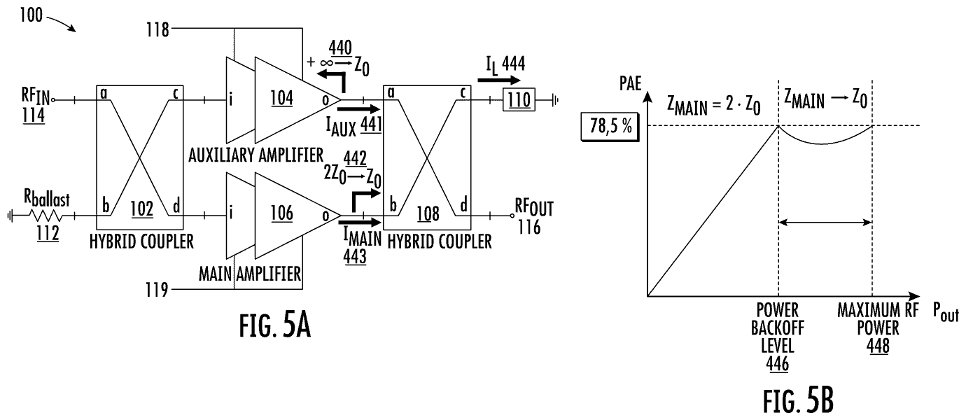

As with the input hybrid coupler 102, the output hybrid coupler 108 may introduce a phase offset between the input signal received at input 108a and the input received at 108b. In an instance in which the phase offset of the input hybrid coupler 102 is equivalent to the input of the output hybrid coupler 108, the phase offset at the output hybrid coupler 108 acts to synchronize the two signals. Thus, as shown in FIG. 1, the auxiliary amplifier output received at input 108a and the main amplifier output received at 108b are synchronized by the output hybrid coupler 108. In addition, the auxiliary amplifier output and the main amplifier output are combined at the output 108d (e.g., second coupler second output). The combined signals (e.g., the auxiliary amplifier output and the main amplifier output) are transmitted as the RF output signal 116. By synchronizing and combining the auxiliary amplifier output and the main amplifier output, a first saturation of the power amplifying circuit 100 may occur at or near the power backoff level and a second saturation may occur at the maximum RF power. Double saturation is further described in FIGS. 4A-5B.

The reference impedance (e.g., optimal impedance) of the output hybrid coupler 108 may be denoted by (Z₀).

As further depicted in FIG. 1, the an example power amplifying circuit 100 includes an inductive load 110 electrically connected to the isolation output 108c (e.g., second coupler first output) of the output hybrid coupler 108. The inductive load 110 is any electrical component that stores received energy in a magnetic field. An inductive load 110 may be a passive electrical component, such as an inductor. An inductor is a passive two-terminal electrical component. An inductor may comprise an insulated wire wound into a coil. Alternatively, when using a monolithic integrated technology, the inductor is obtained by a planar loop drawn at a given metallic level or a connected suite of planar loops integrated each at a different metallic level. In such an embodiment, the metallic path may be designed according to various shapes, including but not limited to round shapes, figure-eight shapes, horse shoe shapes, and so on. In some embodiments, the inductor may be composed of several metallic paths, for example, metallic paths on different metallic layers.

An inductor is characterized by an inductance which is a ratio of the voltage to the rate of change of current, which may be represented in units of Henries. The inductive load 110 may exhibit an impedance between 100 picohenries and 400 picohenries, more preferably between 150 and 300 picohenries, most preferably between 175 and 225 picohenries.

An inductive load 110 reflects a portion of the signal received at the input of the inductive load 110. As depicted in FIG. 1, the reflected portion of the signal may be received at the output 104o of the auxiliary amplifier 104 and/or the output 106o of the main amplifier 106. However, the signal is only reflected towards the output 106o of the main amplifier, as the auxiliary amplifier 104 impedance is very high at low power level. The reflected portion of the signal received at the inductive load 110 may experience a phase shift.

The reflected portion may also experience attenuation. An inductive load 110 may operate according to a quality factor. A quality factor of an inductive load 110 is the ratio of the reactance of the inductive load 110 to the resistance of the inductive load 110 at a given frequency. The impedance of an inductive load 110 may include an imaginary impedance part and a real impedance part. A purely reactive inductive load 110 has an imaginary impedance part that is much greater than the real impedance part of the impedance of the inductive load 110. For example, an imaginary impedance part of the inductive load that is at least a factor of 15 greater than the real impedance part of the inductive load may be considered a purely inductive load or a mostly pure inductive load. For example, a mostly pure inductive load 110 with a real impedance part of the impedance of 50 ohms may have an imaginary part of the impedance greater than 750 ohms.

A reflection coefficient is the ratio between the amplitude of the reflected signal reflected at the inductive load, and the transmitted signal received at the inductive load 110. The reflection coefficient of an inductive load 110 may have a direct impact on the bandwidth of the RF output signal 116. For example, a lower reflection coefficient may reduce the bandwidth of potential output RF signals 116. In some embodiments, the reflection coefficient of the inductive load 110 is above 0.85, more preferably above 0.9, most preferably above 0.95. A reflection coefficient of the inductive load 110 below 0.7 may not support a bandwidth required by some wireless communication protocols.

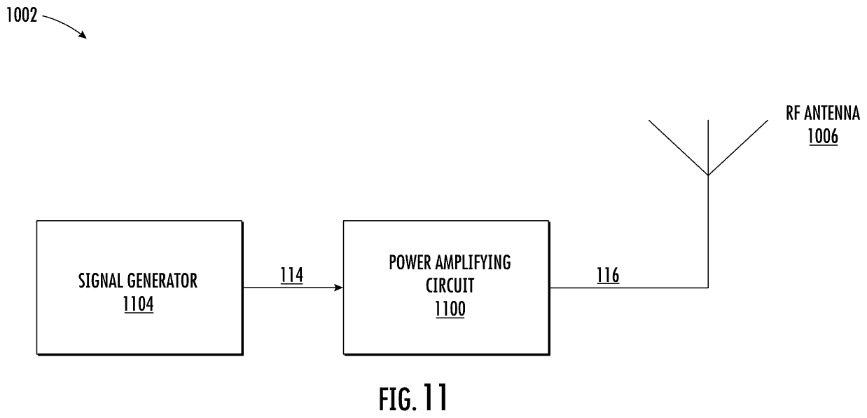

As further depicted in FIG. 1, the an example power amplifying circuit 100 is configured to generate an RF output signal 116. The RF output signal 116 is any electromagnetic wave oscillating at a frequency within the RF spectrum and representing an amplified version of the input RF signal 114. As such, the RF output signal 116 is modulated to encode various forms of data. Modulation encoding techniques may include amplitude modulation (AM), frequency modulation (FM), phase shift keying (PSK), quadrature phase shift keying (QPSK), quadrature amplitude modulation (QAM), and so on. An antenna (as further described in relation to FIG. 11) may be configured to transmit the RF output signal 116, enabling wireless communication between one or more wireless devices.

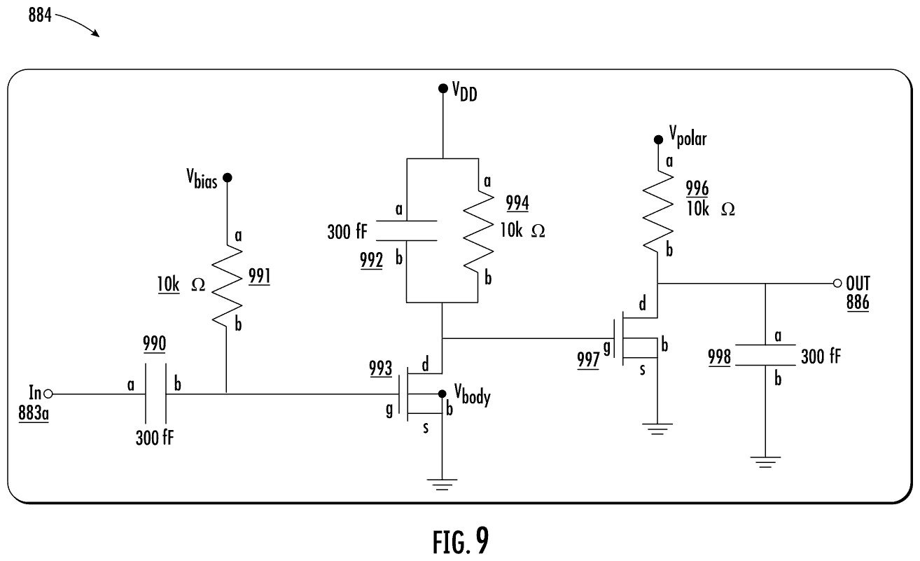

Referring now to FIG. 2, an example auxiliary amplifier 104 is provided. As depicted in FIG. 2, the example auxiliary amplifier 104 is configured to receive an RF signal (e.g., first coupler first output) at the input 104i and generate an amplified signal (e.g., auxiliary amplifier output) at the output 104o. As further depicted in FIG. 2, the example auxiliary amplifier 104 is configured to receive a bias signal 118. The bias signal 118 may be utilized to alter the power operation class at which the auxiliary amplifier 104 is configured to operate. For example, in some embodiments, the auxiliary amplifier 104 may be configured for Class C operation. As described herein, an amplifier configured for Class C operation may operate in a lower power operation class. Enabling the amplifier, for example, in an instance in which the power level of the input signal exceeds the power back-off level of the power amplifying circuit 100. In some embodiments, the bias signal 118 may be between 0 volts and 0.4 volts; more preferably between 0.05 volts and 0.25 volts; most preferably between 0.10 volts and 0.20 volts. In some embodiments, the bias signal 118 may be dynamically altered to change the power operation class of the auxiliary amplifier 104 by adaptive biasing circuitry. Adaptive biasing circuitry is further described in relation to FIG. 8-FIG. 9.

Referring now to FIG. 3, an example main amplifier 106 is provided. As depicted in FIG. 3, the example main amplifier 106 is configured to receive an RF signal (e.g., first coupler second output) at the input 106i and generate an amplified signal (e.g., main amplifier output) at the output 106o. As further depicted in FIG. 3, the example main amplifier 106 is configured to receive a bias signal 119. The bias signal 119 may be utilized to alter the power operation class at which the main amplifier 106 is configured to operate. For example, in some embodiments, the main amplifier 106 may be configured for Class AB operation. As described herein, an amplifier configured for Class AB operation may operate in an extended power operation class. Enabling the amplifier over any power level of the power amplifying circuit 100. In some embodiments, the bias signal 119 may be between 0.3 volts and 0.5 volts; more preferably between 0.35 and 0.45 volts; most preferably between 0.375 volts and 0.425 volts.

Referring now to FIG. 4A, an an example power amplifying circuit 100 during low power operation is provided. Low power operation may occur in an instance in which the input RF signal 114 is at or below the power backoff level 446 of the power amplifying circuit 100.

As depicted in FIG. 4A, during operation of the power amplifying circuit 100, each amplifier (e.g., main amplifier 106, auxiliary amplifier 104) experiences an observed impedance (442, 440) at the output port (106o, 104o) of the amplifier. An observed impedance is impedance present at the output of the amplifier due to the output hybrid coupler 108, the inductive load 110, the other amplifier, and/or any output circuitry. The observed impedance may determine the electrical characteristics of the output of the amplifier.

For example, as depicted in FIG. 4A, during low power operation, the auxiliary amplifier 104 is disabled. Thus, the observed impedance 440 at the auxiliary amplifier 104 is infinite (e.g., extremely high), since no current is flowing. In general, the observed impedance 442 at the main amplifier 106 (Z_{MAIN}) may be determined by the following equation:

$${Z}_{MAIN} = {Z}_{0} \cdot ( 1 + \sqrt{2} \frac{Γ \cdot {I}_{L}}{{I}_{MAIN}} {e}^{j θ} )$$

where Z₀ is the reference impedance of the output hybrid coupler 108, Γ is the reflective coefficient of the inductive load 110, I_{L} is the inductor current 444, I_{MAIN} is the main amplifier current 443, and θ is the phase shift introduced by the inductive load 110.

With the auxiliary amplifier 104 disabled, half of the main amplifier output is transmitted to the inductive load 110. Thus, in an instance in which the auxiliary amplifier 104 is disabled, the observed impedance 442 at the main amplifier 106 may be approximated by the following equation:

$${Z}_{MAIN} = {Z}_{0} \cdot ( 1 + {e}^{j θ} )$$

Thus, the inductive load 110 may be configured such that the phase shift introduced by the inductive load 110 (θ) is equal to 2kπ, where k is a natural number. In an instance in which the phase shift introduced by the inductive load 110 (θ) is equal to 2kπ, where k is a natural number, the term e^{jθ} goes to 1. Thus, Z_{MAIN} is equal to 2Z₀ during low power operation.

FIG. 4B depicts the PAE of the RF output signal 116 during low power operation of the power amplifying circuit 100 depicted in FIG. 4A. As described herein, during low power operation, the observed impedance 442 at the main amplifier 106 (Z_{MAIN}) is approximately 2Z₀. Thus, the main amplifier 106 becomes fully saturated at a power level lower than the maximum RF power 448. The power level at which the main amplifier 106 becomes fully saturated is referred to as the power backoff level 446. In some embodiments, the power amplifying circuit 100 may be configured such that the power backoff level 446 is at a power level 6 dB below the maximum RF power 448 (e.g., 3 dB power backoff from the main amplifier 106 combined with 3 dB theoretical losses from the output hybrid coupler 108). Some communication modulation schemes may require RF output signals 116 to be generated with high peak-to-average power ratio (e.g., 9.6 dB). Saturation of the main amplifier 106 at a deep power backoff level 446 (e.g., greater than 3 dB) enables the generation of the RF output signal 116 at the power backoff level 446. Thus, the RF output signal 116 may be generated at a deep power backoff level 446 with a high PAE (e.g., above 75%). Such performance enables the generation of the RF output signal 116 in accordance with a spectrally efficient modulation scheme.

Referring now to FIG. 5A, an an example power amplifying circuit 100 during high power operation is provided. High power operation may occur in an instance in which the input RF signal 114 is above the power backoff level 446 of the power amplifying circuit 100.

As depicted in FIG. 5A, during high power operation, both the main amplifier 106 and the auxiliary amplifier 104 are operating. In an instance in which both the main amplifier 106 and the auxiliary amplifier 104 are operating, the auxiliary amplifier output and the main amplifier output are transmitted to the inductive load 110 in phase opposition. Thus, there is no signal transmitted to the inductive load 110. Due to this behavior, as the power level of the input RF signal 114 increases past the power backoff level 446, the observed impedance 440 at the auxiliary amplifier 104 moves from positive infinity (or very high) toward the optimal impedance (Z₀) of the auxiliary amplifier 104. Further, as the power level of the input RF signal 114 increases past the power backoff level 446, the observed impedance 442 at the main amplifier 106 moves from to 2Z₀ toward the optimal impedance (Z₀) of the main amplifier 106. Thus, the inductive load 110 has no effect on the observed impedance 442 at the main amplifier 106 as the power level of the input RF signal 114 approaches the maximum RF power 448.

FIG. 5B depicts the PAE of the RF output signal 116 during high power operation of the power amplifying circuit 100 depicted in FIG. 5A. As described herein, during high power operation, the observed impedance 442 at the main amplifier 106 (Z_{MAIN}) is approximately Z₀. Thus, the main amplifier 106 becomes fully saturated for a second time at the maximum RF power 448. Such behavior enables efficient generation of an RF output signal 116 in compliance with a spectrally efficient modulation scheme up to a deep power backoff.

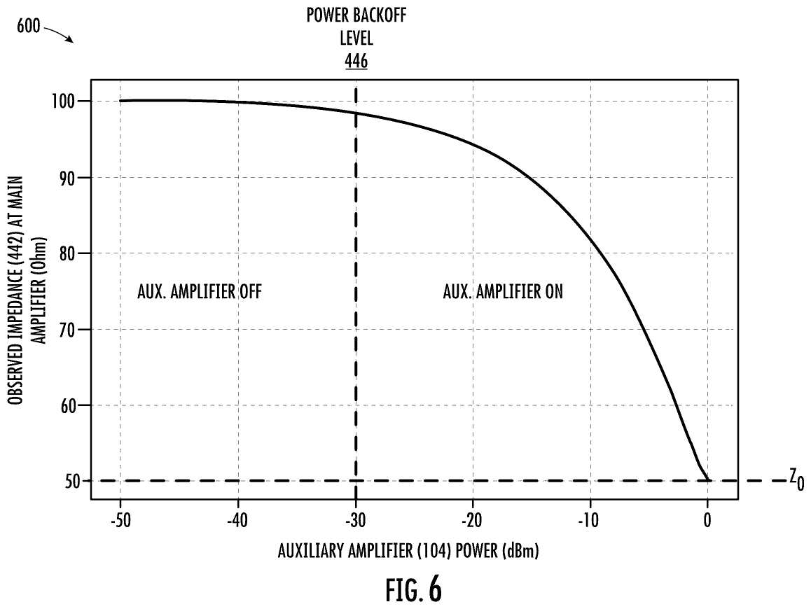

Referring now to FIG. 6, an example graph 600 of the observed impedance 442 at the main amplifier 106 based on the power output of the auxiliary amplifier 104 in decibel-milliwatts (dBm) below the maximum RF power 448 is provided. As depicted in FIG. 6, the power backoff level 446 delimits the left portion of the graph 600 in which the auxiliary amplifier 104 is disabled, and the right portion of the graph 600 in which the auxiliary amplifier 104 is enabled. As depicted in FIG. 6, the optimal impedance (Z₀) is 50 ohms. Thus, during low power operation, in which the auxiliary amplifier 104 is disabled, the observed impedance 442 at the main amplifier 106 is at or near 2Z₀, or 100 ohms. As the power level increases past the power backoff level 446, the auxiliary amplifier 104 is enabled and the observed impedance 442 at the main amplifier 106 begins to decrease. Once the power level reaches the maximum RF power, the auxiliary amplifier 104 is fully enabled and the observed impedance 442 at the main amplifier 106 is Z₀, or 50 ohms.

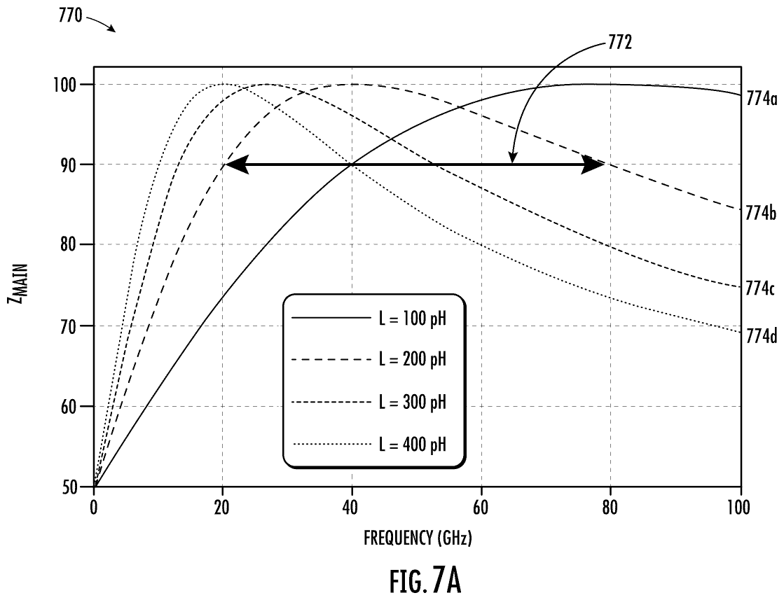

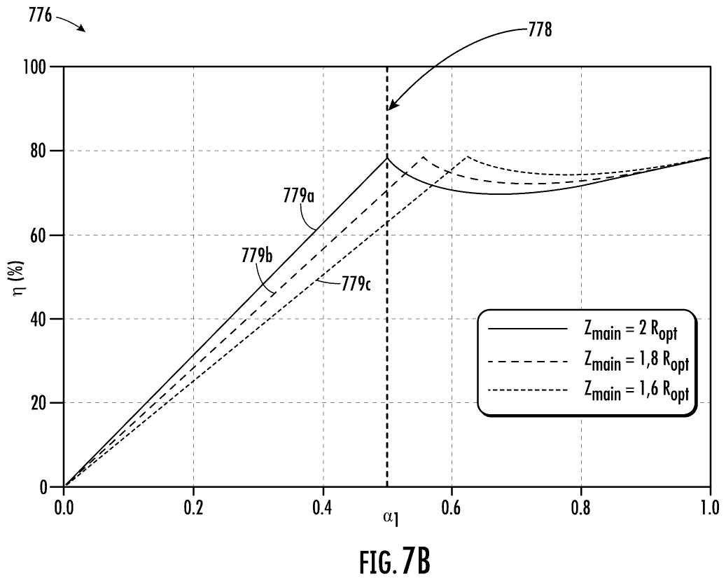

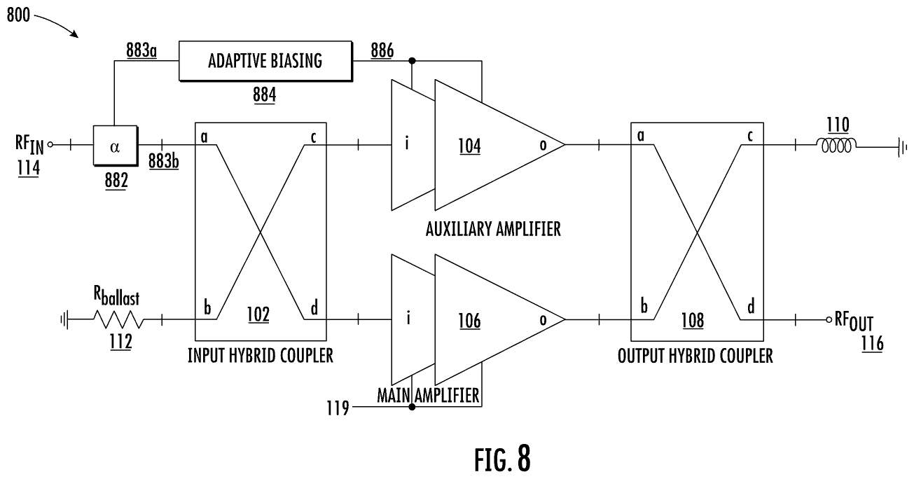

Referring now to FIG. 7A and FIG. 7B, graph 770 and graph 776 depict a bandwidth 772 of an an example power amplifying circuit 100. As depicted in FIG. 7A, graph 770 depicts the observed impedance 442 at the main amplifier 106 (Z_{MAIN}) across a spectrum of frequencies for a plurality of inductance values. As depicted in FIG. 7A, impedance curves (774a-774d) depicting the value of Z_{MAIN} for various impedance values of the inductive load 110, are shown. FIG. 7A is shown for a power amplifying circuit 100 in which the optimal impedance is 50Ω.

Referring now to FIG. 7B, in some embodiments, the bandwidth of a power amplifier (e.g., main amplifier 106) may be defined as the range of frequencies at which the PAE (η) at 6 dB power backoff 778 is above 90% of the maximum theoretical value of PAE. The maximum theoretical PAE value in such an embodiment is 78.5%. Thus, 90% of the maximum theoretical PAE is 70.65%.

The impedance curves 779a-779c show that a decrease in the load (Z_{MAIN}) on the main amplifier 106 leads to an increase in the saturation power of the main amplifier 106. As a result, the PAE at 6 dB power back-off 778 decreases as the impedance (Z_{MAIN}) at the main amplifier 106 decreases. After calculation, the PAE at 6 dB power backoff for Z_{MAIN}=1.8*Rₒₚₜ, where Rₒₚₜ is the optimal impedance, is 70.68%. Thus, the impedance presented to the main amplifier 106 must be greater than 1.8*Rₒₚₜ, for example 90Ω when Rₒₚₜ is 50Ω, to maintain a peak PAE greater than 90% of its maximum efficiency.

Returning to FIG. 7A, the range of frequencies for which the impedance curves 774a-774d are above 1.8*Rₒₚₜ (90Ω) indicate the bandwidth 772 for the associated impedance load. For example, as illustrated in FIG. 7, the impedance curve 774b represents the observed impedance 442 at the main amplifier 106 in an instance in which the inductive load 110 has an inductance of 200 picohenries. The impedance curve 774b is at or above 1.8*Rₒₚₜ (90Ω) from 20 GHz to 80 GHz. Thus, indicating a bandwidth 772 of 60 GHz.

Referring now to FIG. 8, an an example power amplifying circuit 800 including adaptive biasing circuitry 884 is depicted. As depicted in FIG. 8, the an example power amplifying circuit 800 includes an input hybrid coupler 102 (e.g., first hybrid coupler) with one input (102a), one isolation port 102b, and two outputs (102c, 102d). A first input 102a of the input hybrid coupler 102 is electrically connected to a power splitting device 882. The splitting device 882 receives an input RF signal 114 and transmits a portion 883a of the input RF signal 114 to the adaptive biasing circuitry 884 and a portion 883b of the input RF signal 114 to the to the input hybrid coupler 102 on the input 102a. The second input port 102b of the input hybrid coupler 102 is electrically connected to a ballast resistor 112. As further depicted in FIG. 8, the first output 102c of the input hybrid coupler 102 is electrically connected to the input 104i of an auxiliary amplifier 104. Similarly, the second output 102d of the input hybrid coupler 102 is electrically connected to the input 106i of the main amplifier 106. The auxiliary amplifier 104 is further configured to receive an adaptive biasing signal 886 from the adaptive biasing circuitry 884. As further depicted in FIG. 8, the an example power amplifying circuit 800 includes an output hybrid coupler 108 (e.g., second hybrid coupler) having two inputs (108a, 108b) and two outputs (108c, 108d). The first input 108a of the output hybrid coupler 108 is electrically connected to the output 104o of the auxiliary amplifier 104. Similarly, the second input 108b of the output hybrid coupler 108 is electrically connected to the output 106o of the main amplifier 106. The isolation output 108c of the output hybrid coupler 108 is electrically connected to an inductive load 110. The second output 108d is configured to generate the RF output signal 116.

As depicted in FIG. 8, the an example power amplifying circuit 800 includes a power splitter 882. The splitter 882 is any device configured to split the input RF signal 114 into two or more output signals (e.g., portion 883a, portion 883b) with minimal losses. In some embodiments, the portion 883a of the input RF signal 114 transmitted to the adaptive biasing circuitry 884 and the portion 883b of the input RF signal 114 are in phase synchronization.

As depicted in FIG. 8, the an example power amplifying circuit 800 includes adaptive biasing circuitry 884 configured to generate an adaptive biasing signal 886. The adaptive biasing circuitry 884 is any circuitry including hardware and/or software configured to generate an adaptive biasing signal 886 enabling a gradual transition of the auxiliary amplifier 104 from a disabled state during low power operation to an enabled state as an amplifier configured for Class AB operation during high power operation. As depicted in FIG. 8, the adaptive biasing signal 886 is utilized by the power amplifying circuit 800 to bias the auxiliary amplifier 104 based on the portion 883a of the input RF signal 114 received from the splitting device 882. The adaptive biasing signal 886 may alter the power level at which the auxiliary amplifier 104 is enabled. In addition, the adaptive biasing signal 886 may alter the bias class of the auxiliary amplifier 104. For example, the adaptive biasing signal 886 may enable the auxiliary amplifier 104 to transition from a disabled state during low power operation, to a Class C operating amplifier in an instance in which the power level is at or just above the power backoff level, to a Class AB operating amplifier in an instance in which the power level is at or near the maximum RF power level.

By utilizing the adaptive biasing signal 886 to dynamically alter the bias state of the auxiliary amplifier 104, the power amplifying circuit 800 may optimize power consumption of the auxiliary amplifier 104. In addition, the overall linearity of the power amplifying circuit 800 may be improved. An example embodiment of adaptive biasing circuitry 884 is described in relation to FIG. 9.

Referring now to FIG. 9, a non-limiting example embodiment of adaptive biasing circuitry 884 is provided. As depicted in FIG. 9, the example adaptive biasing circuitry 884 is configured to receive a portion 883a of the input RF signal (e.g., input RF signal 114) at a first port 990a of a capacitor 990. The second port 990b of the capacitor 990 is electrically connected to a second port 991b of a resistor 991. The first port 991a of the resistor 991 is electrically connected to a bias voltage (V_{bias}).

The second port 991b of the resistor 991 is further electrically connected to the gate terminal 993g of a first transistor 993. The source terminal 993s of the transistor 993 is electrically connected to an electrical ground. The body terminal 993b of the transistor 993 is electrically connected to a body voltage (V_{body}). The drain terminal 993d of the transistor 993 is electrically connected to a second port 992b of a capacitor 992 and a second port 994b of a resistor 994. The first port 992a of the capacitor 992 is electrically connected to a Vad voltage and to the first port 994a of the resistor 994.

As further depicted in FIG. 9, the drain terminal 993d of the first transistor 993 is electrically connected to a gate terminal 997g of a second transistor 997. The source terminal 997s and the body terminal 997b of the transistor 997 are both electrically connected to electrical ground.

The drain terminal 997d of the transistor 997 is electrically connected to a second port 996b of a resistor 996. The first port 996a of the resistor 996 is electrically connected to a polarization voltage (Vₚₒₗₐᵣ). The source terminal 997s of the transistor 997 is further electrically connected to a first port 998a of a capacitor 998. The second port 998b of the capacitor 998 is electrically connected to electrical ground.

The adaptive biasing signal 886 is transmitted from the drain terminal 997d of the second transistor 997.

As depicted in FIG. 9, in some embodiments, the first transistor 993 and the second transistor 997 may comprise metal-oxide-semiconductor field-effect transistors (MOSFETs). In addition, example values for the resistors depicted in FIG. 9 may include 10 kiloohms for the resistor 991, resistor 994, and resistor 996. Example values for the capacitors depicted in FIG. 9 may include 300 femtofarads for capacitor 990, capacitor 992, and capacitor 998.

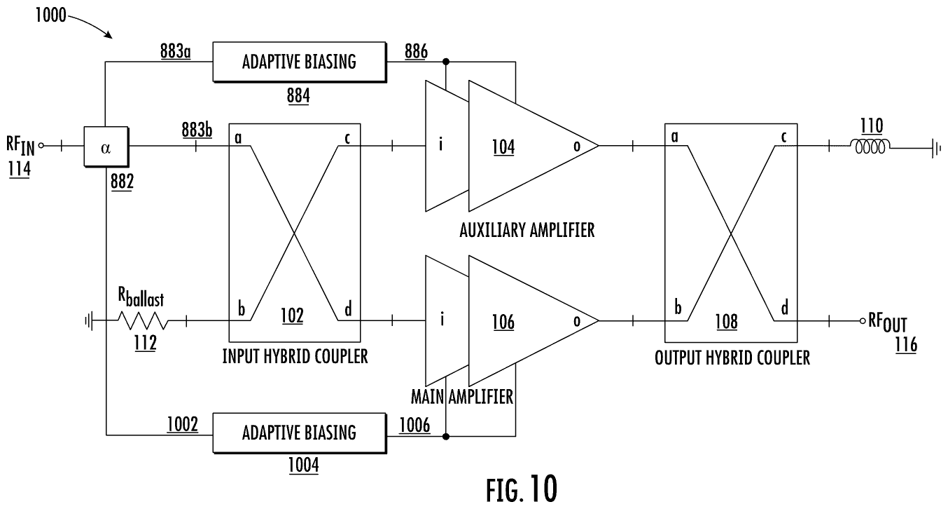

Referring now to FIG. 10, an example power amplifying circuit 1000 including a second adaptive biasing circuitry 1004 configured to generate an adaptive biasing signal 1006 for the main amplifier 106 is depicted. As depicted in FIG. 8, the splitting device 882 receives an input RF signal 114 and transmits a portion 1002 of the input RF signal 114 to the adaptive biasing circuitry 1004. As described herein, the second output 102d of the input hybrid coupler 102 is electrically connected to the input 106i of the main amplifier 106. The main amplifier 106 is further configured to receive an adaptive biasing signal 1006 from the adaptive biasing circuitry 1004.

As depicted in FIG. 10, the an example power amplifying circuit 1000 includes a splitter 882 configured to split a portion 1002 of the input RF signal 114 to be transmitted to the adaptive biasing circuitry 1004. Although depicted as a single splitter 882 in FIG. 10, the splitter 882 may comprise one or more splitters configured to generate a plurality of portions (883a, 883b, 1002).

As depicted in FIG. 10, the an example power amplifying circuit 1000 includes adaptive biasing circuitry 1004 configured to generate an adaptive biasing signal 1006 for the main amplifier 106. The adaptive biasing circuitry 1004 is any circuitry including hardware and/or software configured to generate an adaptive biasing signal 1006 enabling a dynamic bias signal of the main amplifier 106. A dynamic bias signal may enable a transition of the main amplifier 106 between bias classes. For example, an adaptive biasing signal 1006 may enable the main amplifier 106 to transition from a Class AB operating amplifier to a Class C operating amplifier based on the input RF signal 114.

In some embodiments, the auxiliary amplifier 104 and the main amplifier 106 may be biased by adaptive biasing signal 886 and adaptive biasing signal 1006, respectively, for operation in the same power operation class. For example, both the auxiliary amplifier 104 and the main amplifier 106 may be biased for operation in the Class A, or Class AB, or ClassB operating class. In such a configuration, the power amplifying circuit 1000 is configured to operate as a balanced power amplifying circuit 1000. In this case, the inductive load 110 has to show the same (or close to the same) impedance as the reference impedance on the output node 116.

Referring now to FIG. 11, an example RF transmission system 1102 is provided. As depicted in FIG. 11, the example RF transmission system 1102 includes a signal generator 1104 configured to generate an input RF signal 114. The power amplifying circuit 1100 is configured to generate an amplified RF output signal 116 based on the input RF signal 114. As further depicted in FIG. 11, an RF antenna 1106 is electrically coupled to the power amplifying circuit 1100 and configured to transmit the RF output signal 116.

As depicted in FIG. 11, the example RF transmission system 1102 includes a signal generator 1104. A signal generator 1104 is any circuitry including hardware and/or software configured to generate an electromagnetic signal oscillating at a frequency within the RF spectrum and modulated to encode data. A signal generator 1104 may include hardware and/or software to generate a carrier signal operating at frequency within the RF spectrum. The signal generator 1104 may further modulate the carrier signal according to a modulation technique to encode data on the carrier signal. Modulation encoding techniques may include amplitude modulation (AM), frequency modulation (FM), phase shift keying (PSK), quadrature phase shift keying (QPSK), quadrature amplitude modulation (QAM), and so on. The modulated signal encoding data through the modulation technique is transmitted to the power amplifying circuit 1100 as the input RF signal 114.

As further depicted in FIG. 11, the example RF transmission system 1102 includes a power amplifying circuit 1100 in accordance with an example embodiment of the present disclosure (e.g., power amplifying circuit 100, power amplifying circuit 800). The power amplifying circuit 1100 receives the input RF signal 114 and generates an amplified RF output signal 116. The amplified RF output signal 116 is generated with low loss due to the use of hybrid couplers. In addition, the amplified RF output signal 116 is generated with high PAE at deep power backoff levels (e.g., power backoff level of 6 dB below the maximum RF power). The generation of the amplified RF output signal 116 is also resilient to changes in VSWR due to the hybrid coupler-based architecture. Further, the architecture of the power amplifying circuit 1100 enables operation in accordance with wireless transmission protocols at a wide bandwidth (e.g., broadband).

As further depicted in FIG. 11, the example RF transmission system 1102 includes an RF antenna 1106. An RF antenna 1106 is configured to convert an electromagnetic current (e.g., RF output signal 116) carried through a metallic waveguide into the same electromagnetic signal but carried through a transmission medium (e.g., air). Although depicted as a single antenna in FIG. 11, an RF antenna 1106 may include a plurality of RF antennas 1106. Although not depicted in FIG. 11, in some embodiments, an RF transmission system 1102 may include a plurality of RF antennas 1106 configured in an antenna array. Each RF antenna 1106 in the antenna array may receive an RF output signal 116 from a separate power amplifying circuit 1100. The array of antennas 1106 may be arranged into a specific spatial configuration to enable signal transmission according to beamforming techniques at the operation frequency.

While this detailed description has set forth some embodiments of the present invention, the appended claims cover other embodiments of the present invention which differ from the described embodiments according to various modifications and improvements. For example, one skilled in the art may recognize that such principles may be applied to any electronic device that utilizes a power amplifier to amplify an RF signal. For example, a mobile phone, laptop, computer, tablets, gaming systems, virtual reality and/or augmented reality systems, automobiles, unmanned aerial vehicles, sensors, robotic devices, and so on.

Within the appended claims, unless the specific term “means for” or “step for” is used within a given claim, it is not intended that the claim be interpreted under 35 U.S.C. 112, paragraph 6.

Use of broader terms such as “comprises,” “includes,” and “having” should be understood to provide support for narrower terms such as “consisting of,” “consisting essentially of,” and “comprised substantially of” Use of the terms “optionally,” “may,” “might,” “possibly,” and the like with respect to any element of an embodiment means that the element is not required, or alternatively, the element is required, both alternatives being within the scope of the embodiment(s). Also, references to examples are merely provided for illustrative purposes, and are not intended to be exclusive.

1. A power amplifying circuit, comprising:
a first hybrid coupler, configured to receive an input radio frequency (RF) signal and generate a first coupler first output signal and a first coupler second output signal,
wherein the first coupler first output signal and the first coupler second output signal are offset by a phase offset;
an auxiliary amplifier configured to receive the first coupler first output signal, and generate an auxiliary amplifier output;
a main amplifier configured to receive the first coupler second output signal, and generate a main amplifier output; and
a second hybrid coupler comprising a second coupler first output, and a second coupler second output, the second hybrid coupler configured to receive the auxiliary amplifier output and to receive the main amplifier output,
wherein the second coupler first output is electrically connected to an inductive load, and
wherein the auxiliary amplifier output and the main amplifier output are adapted to be combined in synchronization to generate an RF output signal at the second coupler second output.

2. The power amplifying circuit of claim 1, wherein the first hybrid coupler and the second hybrid coupler are ninety-degree hybrid couplers, such that the phase offset of the first coupler first output signal and the first coupler second output signal is ninety degrees.

3. The power amplifying circuit of claim 2, wherein the first hybrid coupler and the second hybrid coupler are twisted hybrid couplers.

4. The power amplifying circuit of claim 1, wherein the main amplifier is biased to amplify the first coupler second output signal in an extended power operation class.

5. The power amplifying circuit of claim 4, wherein the main amplifier is configured for Class AB operation.

6. The power amplifying circuit of claim 1, wherein the auxiliary amplifier is configured for Class C operation.

7. The power amplifying circuit of claim 1, further comprising:
a first adaptive biasing circuitry configured to generate a first adaptive biasing signal based on the input RF signal,
wherein the first adaptive biasing signal defines an auxiliary power operation class of the auxiliary amplifier based on an amplitude of the input RF signal.

8. The power amplifying circuit of claim 7, further comprising:
a second adaptive biasing circuitry configured to generate a second adaptive biasing signal based on the input RF signal,
wherein the second adaptive biasing signal defines a main power operation class of the main amplifier based on the amplitude of the input RF signal.

9. The power amplifying circuit of claim 8, wherein the auxiliary power operation class and the main power operation class are the same class.

10. The power amplifying circuit of claim 1, wherein the main amplifier saturates at a power backoff level lower than a maximum RF power of the main amplifier.

11. The power amplifying circuit of claim 10, wherein the inductive load is a passive electrical component.

12. The power amplifying circuit of claim 11, wherein the inductive load has a reflection coefficient at or above 0.7.

13. The power amplifying circuit of claim 11, wherein an imaginary impedance part of the inductive load is at least a factor of 15 greater than a real impedance part of the inductive load.

14. The power amplifying circuit of claim 11, wherein an impedance of the inductive load is between 100 picohenries and 400 picohenries.

15. The power amplifying circuit of claim 11, wherein the second hybrid coupler is associated with a reference impedance, and wherein an impedance of the inductive load is determined based on the reference impedance.

16. The power amplifying circuit of claim 15, wherein an observed impedance at an output of the main amplifier is two times the reference impedance in an instance in which a power level of the input RF signal is at or below the power backoff level.

17. The power amplifying circuit of claim 16, wherein in an instance in which the input RF signal is above the power backoff level, the observed impedance at the output of the main amplifier is between two times the reference impedance and the reference impedance.

18. The power amplifying circuit of claim 17, wherein in an instance in which the input RF signal is at the maximum RF power, the observed impedance at the output of the main amplifier is the reference impedance.

19. The power amplifying circuit of claim 10, wherein the power backoff level is between three decibels and six decibels below the maximum RF power.

20. A radio frequency (RF) transmission system comprising:
a signal generator configured to generate an input RF signal;
a power amplifying circuit electrically connected to the signal generator, the power amplifying circuit comprising:
a first hybrid coupler configured to receive an input RF signal and generate a first coupler first output signal and a first coupler second output signal,
wherein the first coupler first output signal and the first coupler second output signal are offset by a phase offset;
an auxiliary amplifier configured to receive the first coupler first output signal, and generate an auxiliary amplifier output;
a main amplifier configured to receive the first coupler second output signal, and generate a main amplifier output; and
a second hybrid coupler comprising a second coupler first output, and a second coupler second output, and configured to receive the auxiliary amplifier output and the main amplifier output,
wherein the second coupler first output is electrically connected to an inductive load, and
wherein the auxiliary amplifier output and the main amplifier output are combined in synchronization to generate an RF output signal at the second coupler second output; and
an RF antenna, configured to transmit the RF output signal across a transmission medium.
